(19) United States
(12) Patent Application Publication
(10) Pub. No.: US 2014/0113234 A1
(43) Pub. Date: Apr. 24, 2014

(54) LITHOGRAPHY APPARATUS, AND METHOD OF MANUFACTURING AN ARTICLE

(71) Applicant: CANON KABUSHIKI KAISHA, Tokyo (JP)

(72) Inventors: Atsushi ITO, Utsunomiya-shi (JP); Tomoyuki MORITA, Utsunomiya-shi (JP)

(73) Assignee: CANON KABUSHIKI KAISHA, Tokyo (JP)

(21) Appl. No.: 14/059,067

(22) Filed: Oct. 21, 2013

(30) Foreign Application Priority Data
Oct. 22, 2012 (JP) 2012-232479

(51) Int. Cl. H01J 37/317

(52) U.S. Cl. CPC H01J 37/3174
USPC 430/296; 250/453.11

(57) ABSTRACT

The lithography apparatus forms a pattern on a substrate, comprising a holder configured to hold an original or the substrate, and to be moved, an interferometer configured to measure a position of the holder in a measurement direction which intersects with the upper plane of the holder, a reference member provided on the upper plane and having a reference plane, a measuring device provided so as to face the reference plane and configured to measure a position of the reference plane in the measurement direction, and a controller configured to obtain correction data for correcting a measured value obtained by the interferometer based on the measured value obtained by the interferometer and a measured value obtained by the measuring device.

### BACKGROUND OF THE INVENTION

1. Field of the Invention

The present invention relates to a lithography apparatus, and a method of manufacturing an article using the same.

2. Description of the Related Art

In a lithography process included in a manufacturing process of a semiconductor device and liquid crystal display apparatus and the like, a pattern is formed on a substrate by a lithography apparatus such as a exposure apparatus. For example, the exposure apparatus transfers the pattern of an original (reticle, mask) into a photosensitive substrate (such as a wafer and glass plate with a resist layer formed on the surface) via a projection optical system. A lithography apparatus such as this exposure apparatus positions a stage that holds a substrate (holder) to form a pattern on the substrate. Due to the positioning, the position and attitude of the stage can be measured by an interferometer. Conventionally, in order to improve the positioning precision of the stage, measuring in advance the flatness of a reflecting mirror on the stage which reflects a measuring light of an interferometer, and correcting a measured value of the interferometer based on the flatness, has been done. Japanese Patent Laid-Open No. 2009-302490 discloses an exposure apparatus which measures the flatness of a reflecting mirror for the positioning in a Z-axis direction (vertical direction) using an oblique-incidence focus sensor and a reference substrate having a flat plane, in order to improve the positioning precision in the Z-axis direction.

In this context, in the exposure apparatus disclosed in Japanese Patent Laid-Open No. 2009-302490, the space, which allows the light that heads from the sensor to the flat plane of the reference substrate to pass, is needed between the projection optical system and the stage, since an oblique-incidence focus sensor is utilized. However, the measurement which requires the above space is difficult to implement because the interval between a lens barrel (for example, charged particle optical lens-barrel) and a substrate is narrow, for example, in the case of a lithography apparatus such as a drawing apparatus which performs drawing on the substrate with a charged particle beam such as an electron beam.

### SUMMARY OF THE INVENTION

The present invention provides, for example, a lithography apparatus advantageous to correction of a measurement error of an interferometer.

This invention is a lithography apparatus that forms a pattern on a substrate, comprising a holder configured to hold an original or the substrate, and to be moved, an interferometer configured to measure a position of the holder in a measurement direction that intersects with the upper plane of the holder, a reference member provided on the upper plane and having a reference plane, a measuring device provided so as to face the reference plane and configured to measure a position of the reference plane in the measurement direction, and a controller configured to obtain correction data for correcting a measured value obtained by the interferometer based on the measured value obtained by the interferometer and a measured value obtained by the measuring device.

Further features of the present invention will become apparent from the following description of exemplary embodiments with reference to the attached drawings.

### BRIEF DESCRIPTION OF THE DRAWINGS

FIG. 1 is a side view showing a configuration of the drawing apparatus according to the first embodiment of this invention.

FIG. 2 is a plan view showing a configuration of the drawing apparatus according to the first embodiment of this invention.

FIG. 3 is a side view showing a configuration of the drawing apparatus according to the second embodiment of this invention.

FIG. 4 is a plan view showing a configuration of the drawing apparatus according to the second embodiment of this invention.

### DESCRIPTION OF THE EMBODIMENTS

The modes for implementing this invention are explained below with reference to the drawings and the like.

### First Embodiment

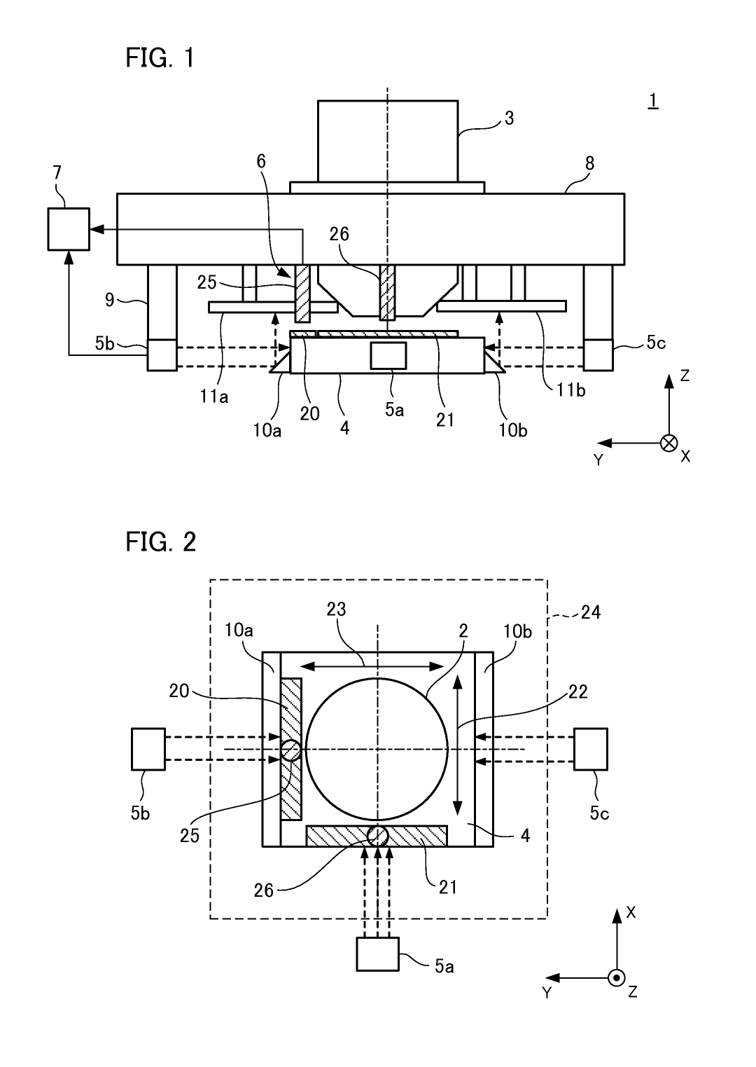

First, a configuration is explained of the lithography apparatus according to the first embodiment of the present invention. A lithography apparatus is an apparatus used in a lithography process of a process for manufacturing a semiconductor device and liquid crystal display apparatus and the like., and is exemplified by a drawing apparatus below in this embodiment. The drawing apparatus is configured to draw a predetermined pattern at a predetermined position of a wafer (substrate) by deflecting a single or a plurality of electron beams (charged particle rays), and controlling blanking (irradiation OFF) of the electron beams. Note that the charged particle ray is not limited to an electron beam (electron ray), but may be for example an ion beam (ion ray). FIG. 1 and FIG. 2 are schematic views showing the configuration of a drawing apparatus 1 according to this embodiment. In particular, FIG. 1 is a side view (front view), and FIG. 2 is a plan view corresponding to the side view of FIG. 1. In FIG. 1 and FIG. 2, a Z-axis is defined in a nominal direction of irradiation of an electron beam relative to a wafer 2, X-axis and Y-axis orthogonal to each other are defined in a plane perpendicular to the Z-axis. The drawing apparatus 1 has an electron beam lens-barrel (also called electron optical lens-barrel or charged particle optical lens-barrel) 3, a substrate stage 4 which holds the wafer 2, an interferometer 5 which measures the position of the substrate stage 4, a measuring device 6 for correction of a measured value of the interferometer 5, and a controller 7. Hereupon, the wafer 2 is a substrate to be treated made of single crystal silicon or the like. A photosensitive resist (photosensitizing agent) is applied to the surface thereof.

The electron beam lens-barrel 3 includes, in the inside, an optical system (not shown) which deflects and images the electron beam emitted from an electron gun and a crossover. The electron gun discharges an electron (electron beam) by application of heat and an electric field. The optical system includes an electrostatic lens, a blanking deflector that enables an electron beam to be shielded, a stopping aperture, and further, a deflector which deflects an image in a specific direction onto the surface of the wafer 2, and the like. This electron beam lens-barrel 3 is supported by a support base 8, and although not illustrated, this support base 8 is fixed to a floor support base that is installed on a floor plane via a prop and the like. Note that, the atmospheric pressure is regulated so as to be a predetermined high vacuum by a vacuum exhaust system (not shown) in the inside of the electron beam lens-barrel 3 in order to prevent or reduce an attenuation of an electron beam and an electric discharge due to high voltage in the elements which constitute the charged particle optical system.

The substrate stage (holder) 4 holds the wafer 2 by, for example, an electrostatic force, while it is movable in all six directions (that is, with six degrees of freedom) of each axial direction of X, Y, Z, and each direction of rotation of θx, θy, θz around each axis. This substrate stage 4 is also installed in a chamber (not shown), and atmospheric pressure is also regulated by a vacuum exhaust system inside the chamber.

The interferometer 5 includes three interferometers of a first interferometer 5a, a second interferometer 5b, and a third interferometer 5c, which are each installed on the support base 8 via props 9, particularly in this embodiment, in order to enable the positions in six directions of the substrate stage 4 to be measured. The first interferometer 5a enables three measuring lights to be irradiated to an X-axis direction toward a reflecting mirror (not shown) installed on a side of the substrate stage 4, as shown in FIG. 2. Due to this first interferometer 5a, the position in an X-axis direction, the rotational attitude θy around an Y-axis, and the rotational attitude θz around an Z-axis of the substrate stage 4, can be measured. The second interferometer 5b enables two measuring lights to be irradiated in a Y-axis direction toward a side of the substrate stage 4, as shown in FIG. 2. Among these two measuring lights, one measuring light is irradiated on a reflecting mirror installed on a side of the substrate stage 4. Due to the reception of this reflected light, the second interferometer 5b can measure the position of the substrate stage 4 in a Y-axis direction. Another measuring light is bent above in a Z-axis direction by a triangular mirror (light path folding mirror) 10a extendedly installed on a side of the substrate stage 4, and reflects on a reference mirror for Z-axis direction 11a supported by the support base 8. This reflected light is bent back at the triangular mirror 10a to return to the second interferometer 5b again. Since the second interferometer 5b can measure the positions including information with regard to a Y-axis direction and Z-axis direction of the substrate stage 4 due to the reception of this reflected light, the position of the substrate stage 4 in a Z-axis direction can be finally evaluated by referring to the position in a Y-axis direction obtained with the above another measuring light. The third interferometer 5c is installed on a side opposed to the second interferometer 5b based on the substrate stage 4 as shown in FIG. 2, and its measuring method is the same as in the second interferometer 5b. A triangular mirror 10b and a reference mirror for Z-axis direction 11b, which are used for measurement by the third interferometer 5c, correspond to the triangular mirror 10a and the reference mirror for Z-axis direction 11a, respectively. In this way, since the position in a Z-axis direction can be obtained from two measurements by using both the second interferometer 5b and the third interferometer 5c in a Y-axis direction, the rotational attitude ex of the substrate stage 4 around an X-axis can be finally evaluated by referring to these two measured values. Note that a configuration of the interferometer 5 is not limited to the above configurations. For example, the second interferometer 5b may be made to have three measuring lights in a Y-axis direction, and the second interferometer 5b may be made to be able to measure the position in a Y-axis direction, the position in a Z-axis direction, and the rotational attitude ex around an X-axis alone. In this case, the third interferometer 5c does not need to be installed.

The measuring device 6 has a plurality of sets (in this embodiment, two sets) of an electrostatic capacity sensor (hereinafter referred to as “sensor”) and a measuring target corresponding to this sensor (target for measurement, hereinafter referred to as “target”). This sensor is an example of a measuring device which measures a distance to a reference plane possessed by a reference member (in this embodiment, target), is of an absolute-type which measures an absolute position, and generally has an advantage of being inexpensive and saving space. At the same time, the target in the event of using this kind of sensor is preferably comprised of, for example, a material with electrical conductivity, and preferably grounded in order to stabilize a measured value of the sensor.

First, as shown in FIG. 2, a first target 20 and a second target 21 are installed one each in an area sandwiched between an adsorption portion which adsorptively holds the wafer 2 and each end in the X, Y-axis directions on the upper plane of the substrate holding side of the substrate stage 4. Among these, the first target 20 is continuously extends in conformity to a stroke in X-axis direction 22 of the substrate stage 4, and its longitudinal length is equal to or greater than the length (distance) of the stroke 22. Similarly, the second target 21 continuously extends in conformity to a stroke in Y-axis direction 23 of the substrate stage 4, and its longitudinal length is equal to or greater than the length of the stroke 23. Hereupon, the stroke (stage stroke) is a movement stroke required for the substrate stage 4 to enable a drawing process to be implemented over substantially all of the surface of the wafer 2, and the distance equal to or greater than at least the diameter of the wafer 2 is set in the X and Y-axis directions, which intersect each other. That is, in the substrate stage 4, highly precise positioning will be required over this stroke. Note that since the stroke also needs to be made longer than the diameter of the wafer 2 for an alignment process other than a drawing process, and the like, the necessary stroke may vary depending on that lithography apparatus. Hereinafter, in this embodiment, with regard to each stroke 22, 23 of the substrate stage 4, the centers of the stage positions are deemed to be the stroke centers in the X and Y-axis directions, and of the distance by the diameter size of the wafer 2, respectively, in order to simplify the explanation. Furthermore, in FIG. 2, as a reference, a range of movement 24 of the substrate stage 4, for which it can move by making each stroke 22 and 23 such a distance, is shown by dotted lines.

With respect to these installation positions of the first target 20 and the second target 21, a first sensor 25 and a second sensor 26 are installed one by one in the support base 8. Among these, the first sensor 25 measures the position of the first target 20 in a Z-axis direction (measuring direction). This first sensor 25 is disposed in a XY-plane so as to measure the center of the first target 20 in an X-axis direction when the substrate stage 4 is in the center of each stroke 22, 23 (reference position of the stage), as shown in FIG. 2. Meanwhile, the second sensor 26 measures the position of the second target 21 in a Z-axis direction. Similarly to the case of the first sensor 25, this second sensor 26 is disposed in an XY-plane so as to measure the center of the second target 21 in a Y-axis direction when the substrate stage 4 is in the reference position. By disposing the first sensor 25 and the second sensor 26 in this way, the size on an XY-plane of the substrate stage 4, in which the first target 20 and the second target 21 are installed, can be reduced as possible.

The controller 7 is comprised of, for example a computer and the like, connected to each component of the drawing apparatus 1 via a circuit, and can execute control of each component in accordance with a program, and the like. In particular, the controller 7 at least executes calculation to correct a measured value of the interferometer 5 in a Z-axis direction with reference to measured values of the first sensor 25 and the second sensor 26, as will be mentioned below. Note that the controller 7 may be configured integrally with other parts of the drawing apparatus 1 (within a shared housing), and may be configured separately from other parts of the drawing apparatus 1 (within separate housings).

Next, a correcting process is explained for correcting a measured value of the interferometer 5 in the drawing apparatus 1. As the drawing apparatus 1 implements a drawing process on the wafer 2 on the substrate stage 4, the controller 7 controls positioning operation of the substrate stage 4. At this time, the controller 7 determines the position of the substrate stage 4 in each direction with reference to a measured value due to the interferometer 5 (first interferometer 5a to third interferometer 5c). However, since reflecting mirrors (a collective term for triangular mirrors 10a, 10b and reference mirrors 11a, 11b) that reflect the measuring light of the interferometer 5 are not completely planar but have distortion and inclination, a measured value of the interferometer 5 via these reflecting mirrors will be a value including error due to this distortion and inclination. Specifically, when the substrate stage 4 moves to an X-axis direction, the distortion and inclination of the triangular mirrors 10a and 10b cause an error in a measured value in a Z-axis direction. Meanwhile, when the substrate stage 4 moves to a Y-axis direction, the distortion and inclination of the reference mirrors 11a and 11b cause an error in a measured value in a Z-axis direction. Thereupon, the drawing apparatus 1 measures the (absolute) position of the substrate stage 4 (the first target 20 and the second target 21) based on the support base 8 which supports the interferometer 5 using the measuring device 6, apart from positional measurement by the interferometer 5. To begin with, the controller 7 moves the substrate stage 4 from the stage reference position to an X-axis direction, while it causes the interferometer 5 and the first sensor 25 to implement positional measurement over the stroke in an X-axis direction to acquire its measured value. Similarly, the controller 7 moves the substrate stage 4 from the stage reference position to a Y-axis direction, while it causes the interferometer 5 and the second sensor 26 to implement positional measurement over the stroke in a Y-axis direction to acquire its measured value. At this time, since the measured values of the first sensor 25 and the second sensor 26, that is, the positions (attitudes) of the substrate stage 4 in a Z-axis direction have been measured without a reflecting mirror, it is not affected by the distortion and inclination of the reflecting mirror, and the like. Therefore, the controller 7 can evaluate the correction data for correcting an error of a measured value of the interferometer 5 in a Z-axis direction by the planarity (flatness) by referring to the measured values due to the first sensor 25 and the second sensor 26.

Moreover, the correction precision in the event of utilizing an electrostatic capacity sensor and targets as above depends on the plane precision (planarity) of the targets (first target 20 and second target 21). Therefore, it is desirable to prepare targets having appropriate planarity, depending on necessary correction precision. For example, if highly precise correction is required, the targets are made flattened for their flatness to meet necessary precision. Also, if the planarity of the targets unfavorably varies due to attaching the targets on the substrate stage 4, a value measured for the planarity of the targets by means of a measuring apparatus such as a Fizeau interferometer can be further utilized for correction, with the targets attached on the substrate stage 4. Alternatively, one may use a configuration comprising two sensors (for example, first sensors 25) for one target (for example, first target 20). In this case, the correction data is evaluated based on the measured values of the two sensors by causing these sensors to measure the same portion of the target without being affected by or by reducing the planarity of the target.

Also, although an absolute-type electrostatic capacity sensor has been adopted as a sensor that constitutes the measuring device 6 (or measuring device 35) in this embodiment, this invention is not limited thereby. For example, the measuring device 6 may be configured to adopt an imaging element as a sensor, and further, adopt an extendedly installed flat plate with a mark formed on it as a measuring target on the substrate stage 4. In this case, the sensor may be configured to image a mark via an optical system, and measure the position of the measuring target in a Z-axis direction from the variation in the contrast of the image.

Furthermore, although the example of a drawing apparatus has been explained as a lithography apparatus in this embodiment, the lithography apparatus is not limited thereby. For example, it may be an exposure apparatus that projects a pattern of an original (reticle, mask) on a substrate via a projection optical system, or an imprint apparatus which molds an imprint material on a substrate using a mold to form a pattern on the substrate. Hereupon, in the example of the drawing apparatus 1, the measuring device 6 can perform measurement even when the gap (interval) between the electron beam lens-barrel 3 and the substrate stage 4 is narrow, as shown in FIG. 1. Also in the cases of the above-mentioned other exposure apparatus and imprint apparatus, there will be a similar effect if the configuration of this embodiment is applied, since there is a lens-barrel instead of the electron beam lens-barrel, and a format holder.

As described above, according to this embodiment, a lithography apparatus advantageous for correcting a measurement error of an interferometer related to the flatness of a reflecting mirror, can be provided.

### Second Embodiment

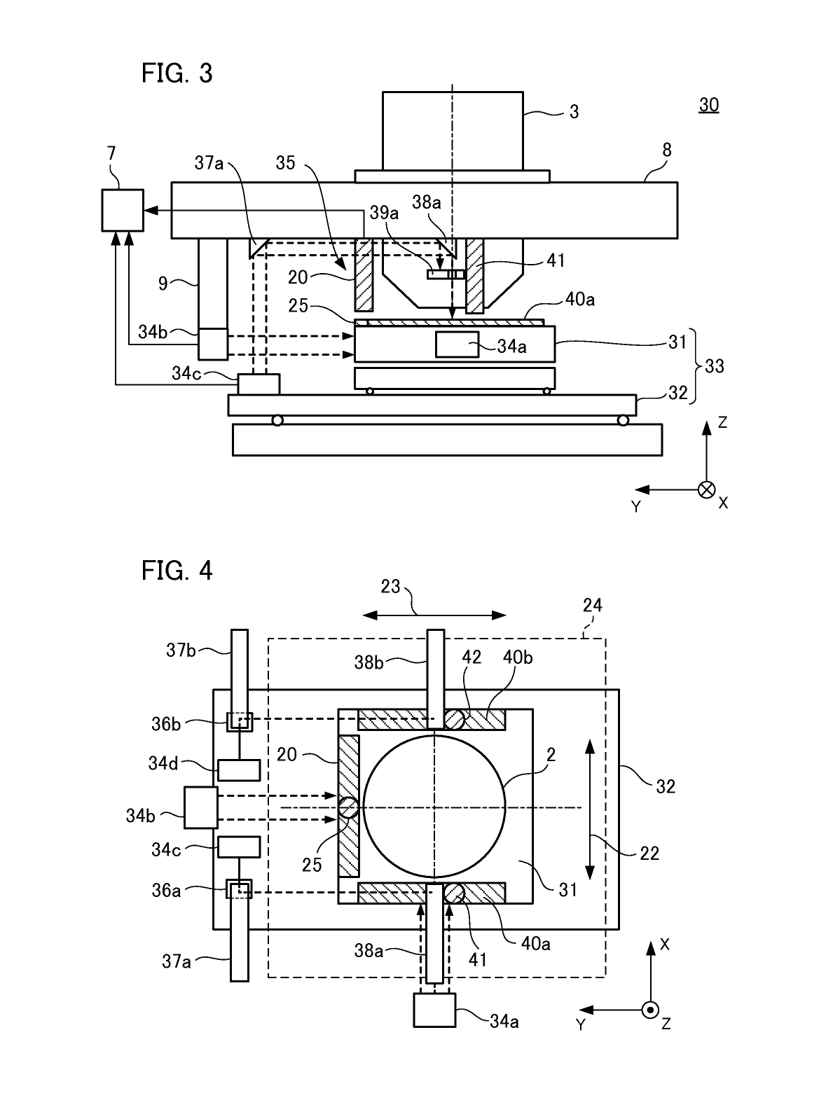

Next, the lithography apparatus according to the second embodiment of this invention is explained. The features of the lithography apparatus according to this embodiment lie in changing the configuration of the substrate stage 4 of the drawing apparatus 1 according to the first embodiment, and along with this, also changing the configurations of the interferometer 5 and the measuring device 6. FIG. 3 and FIG. 4 are schematic views showing a configuration of a drawing apparatus 30 according to this embodiment, which respectively correspond to FIG. 1 and FIG. 2 showing a configuration of the drawing apparatus 1 according to the first embodiment. In particular, FIG. 3 is a side view, and FIG. 4 is a plan view corresponding to the side view of FIG. 3. Note that in FIG. 3 and FIG. 4, the same symbol is assigned to the article whose configuration is the same as that shown in FIG. 1 and FIG. 2, and the explanation thereof is omitted. To begin with, the drawing apparatus 30 has a substrate stage 33 including a fine-motion stage 31 which holds the wafer 2 and is movable in six directions, and a coarse-motion stage 32 that movably supports this fine-motion stage 31 and that is movable in an X-axis direction, instead of the substrate stage 4 of the first embodiment. Furthermore, the drawing apparatus 30 has an interferometer 34 and a measuring device 35, instead of the interferometer 5 and the measuring device 6 of the first embodiment.

To begin with, the interferometer 34 includes two interferometers, a first interferometer 34a and a second interferometer 34b, which are each installed on the support base 8 via the props 9, in this embodiment, in order to measure the position of the fine-motion stage 31. The first interferometer 34a irradiates three measuring lights to an X-axis direction toward an reflecting mirror (not shown) installed on a side of the fine-motion stage 31, as shown in FIG. 4. Due to this first interferometer 34a, the position in an X-axis direction, the rotational attitude θy around an Y-axis, and the rotational attitude θz around an Z-axis of the fine-motion stage 31, can be measured. The second interferometer 34b enables two measuring lights to be irradiated to a Y-axis direction toward a side of the fine-motion stage 31, as shown in FIG. 4. Due to this second interferometer 34b, the position in a Y-axis direction, the rotational attitude θx around an X-axis of the fine-motion stage 31, can be measured.

The interferometer 34 further includes two interferometers, a third interferometer 34c and a fourth interferometer 34d, which are each installed on the coarse-motion stage 32, in this embodiment, in order to measure the position of the fine-motion stage 31 in a Z-axis direction. The third interferometer 34c irradiates two measuring lights to a Y-axis direction toward a triangular mirror 36a installed on a minus side in an X-axis direction on the coarse-motion stage 32, as shown in FIG. 4. These two measuring lights are bent together above in a Z-axis direction by the triangular mirror 36a, and travel to a first triangular mirror 37a extendedly installed in an X-axis direction of the support base 8. The two measuring lights reflected in the first triangular mirror 37a travel along a Y-axis direction, and head to a second triangular mirror 38a provided in the position which overlaps the center of the electron beam lens-barrel 3 in a Y-axis direction. Then, one measuring light among the two measuring lights reflected in the second triangular mirror 38a is irradiated on a first reference mirror 39a supported parallel to the support base 8 above the fine-motion stage 31. The third interferometer 34c receives the reflected light from this first reference mirror 39a as the reference light for measuring the position of the fine-motion stage 31 in a Z-axis direction. Another measuring light is irradiated on a first reflecting plate (reflecting mirror) 40a provided on the fine-motion stage 31. The third interferometer 34c receives the reflected light from this first reflecting plate 40a. Then, the position of the fine-motion stage 31 in a Z-axis direction is measured based on the two reflected lights received. Hereupon, the first reflecting plate 40a is provided in an area except for the area of the holder which holds the wafer 2, on the upper plane of the fine-motion stage 31. Also, the first reflecting plate 40a is installed so as to extend in conformity to the stroke 23 in Y-axis direction of the fine-motion stage 31, and its longitudinal length is equal to or greater than the length of the stroke 23.

In FIG. 4, the third interferometer 34c can implement positional measurement when the position of the fine-motion stage 31 is in a negative X-coordinate based on the center of the electron beam lens-barrel 3 in an XY-plane. In contrast, the fourth interferometer 34d has the components similar to those of the third interferometer 34c, and can implement positional measurement when the position of the fine-motion stage 31 is in a positive X-coordinate. Note that in FIG. 4, the symbol of each component of the fourth interferometer 34d is made by changing the alphabet characters from “a” to “b” in the symbol of each component of the third interferometer 34c. Furthermore, positional measurement is possible in any of the third interferometer 34c and the fourth interferometer 34d when the fine-motion stage 31 is in the vicinity of the center of each stroke 22 and 23, as the state shown in FIG. 4.

Hereupon, the controller 7 refers to a measured value due to the interferometer 34 (first interferometer 34a—fourth interferometer 34d) for control of positioning operation of the substrate stage 33. However, similarly to the first embodiment, reflecting mirrors (a collective term for first reference mirror 39a and first reflecting plate 40a) that reflect the measuring light of the interferometer 34 are not completely planar but have distortion and inclination, a measured value of the interferometer 34 will be a value including the error related to the planarity of the reflecting mirrors. Specifically, the flatness of the reflecting mirrors in an optical path including the first reference mirror 39a (or a second reference mirror (not shown)) causes an error in a measured value when the fine-motion stage 31 moves in an X axis direction. Thereupon, similar to the first embodiment, the drawing apparatus 30 also measures the (absolute) position of the fine-motion stage 31 based on the support base 8 using the measuring device 35.

Similar to the measuring device 6 of the first embodiment, the measuring device 35 has a set of an electrostatic capacity sensor and a measuring target corresponding to this sensor. Hereupon, a set of the first sensor 25 and the first target 20 which measures the (absolute) position of the fine-motion stage 31 in a Z-axis direction along an X-axis direction is similar to that of the first embodiment, as shown in FIG. 4. In contrast, the measuring device 35 in this embodiment includes the first reflecting plate 40a and a second reflecting plate 40b. The first reflecting plate 40a and the second reflecting plate 40b can be utilized (shared) as-is as a target for electrostatic capacity sensor, if a reflecting plane is formed on a flat plane of their base materials by means of aluminum vapor depositing, and the like. Also in this case, the aluminum vapor-deposited plane is desirably grounded in order to stabilize the measured values of the sensor. In this embodiment, it is a second sensor 41 that is provided on the support base 8 instead of the second sensor 26 of the first embodiment, and the measuring target corresponding to this second sensor 41 is the first reflecting plate 40a. Furthermore, when projected on an XY plane, it is a third sensor (ancillary sensor for the second sensor 41) 42 that is provided in a position symmetric to the second sensor 41 based on the center of the electron beam lens-barrel 3, and the measuring target corresponding to this third sensor 42 is the second reflecting plate 40b. In this circumstance, in the examples shown in FIG. 3 and FIG. 4, the disposition of the second sensor 41 and the third sensor 42 is a slightly offset from the exact center of the stroke in Y-axis direction 23 to a Y-axis direction. This is to keep the measuring light of the interferometer 34 unblocked. Note that bringing the position of the sensor close to the center of the stroke in Y-axis direction 23, as far as the measuring light is kept unblocked, is advantageous in reducing the size of the fine-motion stage 31 in the event of being projected on an XY plane.

It is advantageous in the correction precision of a measured value by making such a configuration, since the drawing apparatus 30 has a similar effect to that of the first embodiment, while the sensor measures a reflecting mirror itself on the fine-motion stage 31 used for measurement by the interferometer 34. Furthermore, in this embodiment, the positions (planarity) of two reflecting plates of the first reflecting plate 40a and the second reflecting plate 40b in a Z-axis direction are concurrently measured using two sensors of the second sensor 41 and the third sensor 42. In this way, it is advantageous in shortness of the time required for measurement to concurrently measure the positions of two reflecting plates. Note that if one of the second sensor 41 and the third sensor 42 is configured as the measuring device 35, it is not imperative to configure the other.

### (Article Manufacturing Method)

An article manufacturing method according to an embodiment of the present invention is preferred in manufacturing an article such as a micro device such as a semiconductor device or the like, an element or the like having a microstructure, or the like. The article manufacturing method may include a step of forming a pattern (for example, latent image pattern) on an object (for example, substrate on which a photosensitive material is coated) using the aforementioned lithography apparatus; and a step of processing (for example, step of developing) the object on which the latent image pattern has been formed in the previous step. Furthermore, the article manufacturing method may include other known steps (oxidizing, film forming, vapor depositing, doping, flattening, etching, resist peeling, dicing, bonding, packaging, and the like). The device manufacturing method of this embodiment has an advantage, as compared with a conventional device manufacturing method, in at least one of performance, quality, productivity and production cost of a device.

While the present invention has been described with reference to exemplary embodiments, it is to be understood that the invention is not limited to the disclosed exemplary embodiments. For example, in the above embodiments, examples have been explained in which this invention is applied to the measurement of the position of a movable holder of the lithography apparatus having the holder which holds the substrate. However, this invention may be applied to the measurement of the position of a movable holder of the lithography apparatus having the holder which holds an original (mask, reticle) or a format, and the like. Also, although the holder has two degrees of freedom of motion within a plane parallel to its upper plane (XY-plane) in the above embodiments, the may be one degree of freedom of motion (that is, movable in only one direction).

This application claims the benefit of Japanese Patent Application No. 2012-232479 filed on Oct. 22, 2012, which is hereby incorporated by reference herein in its entirety.

What is claimed is:

1. A lithography apparatus which forms a pattern on a substrate, the apparatus comprising:
a holder configured to hold an original or the substrate, and to be moved;
an interferometer configured to measure a position of the holder in a measurement direction which intersects with an upper plane of the holder;
a reference member provided on the upper plane and having a reference plane;
a measuring device provided so as to face the reference plane and configured to measure a position of the reference plane in the measurement direction; and
a controller configured to obtain correction data for correcting a measured value obtained by the interferometer based on the measured value obtained by the interferometer and a measured value obtained by the measuring device.

2. The lithography apparatus according to claim 1, further comprising a support base configured to support the interferometer and the measuring device.

3. The lithography apparatus according to claim 1,
wherein the reference member extends in one direction as a longitudinal direction on the upper plane, and
wherein the controller is configured to obtain the correction data with regard to each of a plurality of positions of the holder in the longitudinal direction.

4. The lithography apparatus according to claim 1,
wherein two of the reference member are provided, the two reference members extending in respective directions, intersecting with each other, as longitudinal directions on the upper plane, and
wherein two of the measuring device are provided, the two measuring devices respectively corresponding to the two reference members.

5. The lithography apparatus according to claim 1,
wherein the measuring device is disposed so as to face a center of the reference member if the holder is at a center of a movable range thereof.

6. The lithography apparatus according to claim 1,
wherein the measuring device includes an electrostatic capacity sensor, and
wherein the reference member has electrical conductivity.

7. The lithography apparatus according to claim 1,
wherein the reference member is configured as a reflective member for reflecting a measuring light of the interferometer.

8. The lithography apparatus according to claim 1,
wherein a plurality of the measuring device are provided for the reference member.

9. A method of manufacturing an article, the method comprising:
forming a pattern on a substrate using a lithography apparatus; and
processing the substrate, on which the pattern has been formed, to manufacture the article,
wherein the lithography apparatus includes:
a holder configured to hold an original or the substrate, and to be moved;
an interferometer configured to measure a position of the holder in a measurement direction which intersects with an upper plane of the holder;
a reference member provided on the upper plane and having a reference plane;
a measuring device provided so as to face the reference plane and configured to measure a position of the reference plane in the measurement direction; and
a controller configured to obtain correction data for correcting a measured value obtained by the interferometer based on the measured value obtained by the interferometer and a measured value obtained by the measuring device.
